(19) United States
(12) Patent Application Publication
(10) Pub. No.: US 2015/0034158 A1
(43) Pub. Date: Feb. 5, 2015

(54) SOLAR CELL MODULE AND PHOTOVOLTAIC POWER GENERATION DEVICE

(71) Applicant: Sharp Kabushiki Kaisha, Osaka-shi (JP)

(72) Inventors: Hideki Uchida, Osaka-shi (JP); Hideomi Yui, Osaka-shi (JP); Tokiyoshi Umeda, Osaka-shi (JP)

(73) Assignee: Sharp Kabushiki Kaisha, Osaka-shi (JP)

(21) Appl. No.: 14/379,510

(22) PCT Filed: Feb. 14, 2013
(86) PCT No.: PCT/JP2013/053462

§ 371 Date: Aug. 19, 2014

(30) Foreign Application Priority Data
Feb. 23, 2012 (JP) 2012-037760

(51) Int. Cl. H01L 31/055

(52) U.S. Cl. CPC H01L 31/055
USPC 136/257

(57) ABSTRACT

A solar cell module capable of suppressing a decrease of a light gathering function with use and offering an excellent light gathering function over a long period of time, and a photovoltaic power generation device using the solar cell module are provided.

A solar cell module 1 includes a light gathering member 2 formed of a fluorescent material 7 provided in a transparent base material 6, the light gathering member 2 absorbing external light by the fluorescent material 7 and causing emitted light to propagate to be emitted from an end face 2c, and a solar cell element 3 installed on the end face 2c of the light gathering member 2, the solar cell element 3 receiving the light and generating electric power. The fluorescent material 7 in the light gathering member 2 has an increasing range in which, in a relation between its concentration and light emission intensity obtained from the light gathering member 2 with light emission of the fluorescent material 7, the light emission intensity increases as the concentration increases from zero, and the concentration of the fluorescent material 7 in the transparent base material 6 is set higher than a concentration with which the light emission intensity becomes largest in the increasing range.

### TECHNICAL FIELD

The present invention relates to a solar cell module and photovoltaic power generation device.

### BACKGROUND ART

As a photovoltaic power generation device in which a solar cell element is installed on an end face of a light guiding material and light propagating through the inside of the light guiding material is caused to enter the solar cell element for electric power generation, a solar energy converter described in PTL 1 has been known. This solar energy converter generates electric power by causing a fluorescent material to emit and guide light by sunlight entering the inside of a light guiding plate and causing light to be propagated to a solar cell installed on the end face.

Also, PTL 2 suggests a light planar concentrator having a plurality of laminated light concentrate plates with a fluorescent coating dispersed in a transparent plate, the light planar concentrator configured so that a shorter absorption wavelength of a fluorescent dye is set in a light concentrate plate closer to a light incident side, thereby increasing the light gathering amount per unit area.

### CITATION LIST

### Patent Literature

PTL 1: Japanese Unexamined Patent Application Publication No. 58-49860

PTL 2: Japanese Unexamined Patent Application Publication No. 63-159812

### SUMMARY OF INVENTION

### Technical Problem

Meanwhile, in the solar energy converter of PTL 1 and the light planar concentrator of PTL 2, a fluorescent material is used for the purpose of light gathering of sunlight. Since light of wavelengths as many as possible in sunlight can be desirably used, an organic fluorescent material excellent in this capability is mainly used as the fluorescent material.

The organic fluorescent material absorbs its own absorption wavelength components from sunlight and emits light via an excited state. This excited state is an active state, and the probability of going through a process other than light emission, such as a chemical reaction or energy transfer, significantly increases. That is, in the active state (excited state), the possibility of reacting with a trace quantity of moisture, oxygen, or impurities contained in the periphery of the fluorescent material or, in some cases, its own adjacent molecules increases. Once this reaction occurs, the fluorescent material is changed into a different substance to significantly decrease light emission efficiency or is changed into a substance which never emits light again.

Moreover, as for the organic fluorescent material, energy which dissociates interatomic bonding is in a wavelength region of ultraviolet light, and interatomic bonding is broken by ultraviolet light into degradation. The organic fluorescent material molecules after degradation lose light emission capability.

Therefore, in the solar energy converter and the light concentrator (photovoltaic power generation device) with the use of the above-described organic fluorescent material, the light gathering function is significantly decreased with use.

The present invention has been made in view of the above-described circumstances, and has an object of providing a solar cell module capable of suppressing a decrease in a light gathering function with use and offering an excellent light gathering function over a long period of time, and a photovoltaic power generation device using the solar cell module.

### Solution to Problem

To achieve the object described above, the present invention provides a solar cell module including a light gathering member formed of a fluorescent material provided in a transparent base material, the light gathering member absorbing light entering from outside by the fluorescent material and causing light emitted from the fluorescent material to propagate inside to be emitted from at least one end face, and a solar cell element installed on the end face of the light gathering member, the solar cell element receiving the light emitted from the end face and generating electric power, wherein the fluorescent material in the light gathering member has an increasing range in which, in a relation between a concentration of the fluorescent material in the transparent base material and light emission intensity obtained from the light gathering member with light emission of the fluorescent material, the light emission intensity increases as the concentration increases from zero, and the concentration of the fluorescent material in the transparent base material is set higher than a concentration with which the light emission intensity becomes largest in the increasing range.

### Advantageous Effects of Invention

According to the present invention, the fluorescent material in the light gathering member has an increasing range in which, in a relation between a concentration of the fluorescent material in the transparent base material and light emission intensity obtained from the light gathering member with light emission of the fluorescent material, the light emission intensity increases as the concentration increases from zero, and the concentration of the fluorescent material in the transparent base material is set higher than a concentration with which the light emission intensity becomes largest in the increasing range. Thus, in particular, a decrease in light emission intensity of the light gathering member at an initial stage is suppressed. Therefore, the solar cell module having this light gathering member and the photovoltaic power generation device using the solar cell module offer an excellent light gathering function over a long period of time.

### BRIEF DESCRIPTION OF DRAWINGS

FIG. 1 is a perspective view depicting a schematic structure of a first embodiment of a solar cell module of the present invention.

FIG. 2 is a sectional view of a main part side of FIG. 1.

FIG. 3 is a diagram depicting variations with time of light emission intensity of a light concentrate plate.

FIG. 4 is a diagram depicting variations with time of absorbance of the light concentrate plate.

FIG. 5 is a diagram depicting a relation between decrease in absorbance and decrease in PL intensity.

FIG. 6 is a diagram depicting a relation between concentration and PL intensity and fluorescence quantum yield of a fluorescent material.

FIG. 7 is a diagram depicting a relation between concentration and PL intensity of the fluorescent material.

FIG. 8 is a diagram depicting a relation between concentration and PL intensity and fluorescence quantum yield of the fluorescent material.

FIG. 9 is a diagram depicting a relation between concentration and PL intensity of the fluorescent material.

FIG. 10 is a diagram depicting a relation between concentration and PL intensity and fluorescence quantum yield of the fluorescent material.

FIG. 11 is a diagram depicting a relation between concentration and PL intensity of the fluorescent material.

FIG. 12 is a diagram depicting absorption spectrums.

FIG. 13 is a diagram depicting a spectrum after sunlight is absorbed.

FIG. 14 is a diagram depicting a relation between conversion efficiency and wavelength of each of solar cells of various types.

FIG. 15 is a sectional view of a main part side depicting a schematic structure of a second embodiment of the solar cell module of the present invention.

FIG. 16 is a diagram depicting a relation between concentration and PL intensity and fluorescence quantum yield of a fluorescent material.

FIG. 17 is a diagram depicting a relation between concentration and PL intensity and fluorescence quantum yield of the fluorescent material.

FIG. 18 is a diagram depicting a relation between concentration and PL intensity of the fluorescent material.

FIG. 19 is a diagram depicting a spectrum after sunlight is absorbed.

FIG. 20 is a schematic diagram depicting a schematic structure of a third embodiment of the solar cell module of the present invention.

FIG. 21 is a diagram depicting a spectrum after sunlight is absorbed.

FIG. 22 is a diagram describing the operation of a light concentrate plate depicted in FIG. 20.

FIG. 23 is a schematic diagram depicting a schematic structure of a fourth embodiment of the solar cell module of the present invention.

FIG. 24 is a diagram depicting variations with time of a light emission spectrum.

FIG. 25 is a diagram depicting variations of the molecular structure of the fluorescent material and an absorption spectrum and light emission spectrum in each molecular structure.

FIG. 26 is a schematic diagram depicting modification examples of the third embodiment and the fourth embodiment.

FIG. 27 is a schematic structural view of a photovoltaic power generation device.

### DESCRIPTION OF EMBODIMENTS

The present invention is described in detail below. Note that the scale of each component is changed as appropriate so that each component has a recognizable size.

### First Embodiment

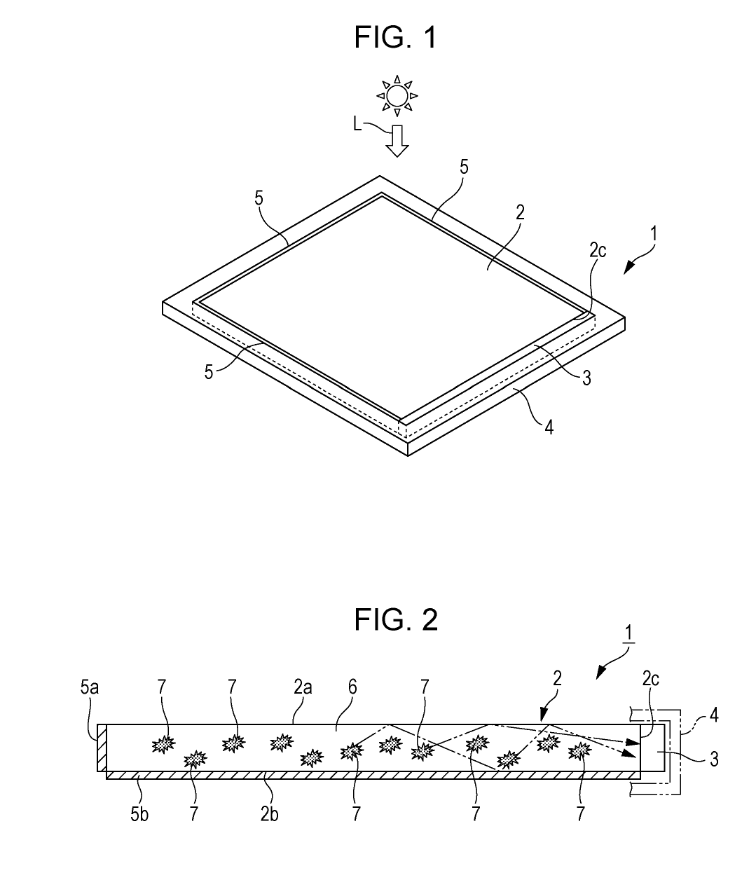

FIG. 1 is a perspective view of a schematic structure of a first embodiment of a solar cell module according to the present invention, and FIG. 2 is a sectional view of a main part side of FIG. 1.

As depicted in FIG. 1 and FIG. 2, a solar cell module 1 is configured to include a light concentrate plate 2 (light gathering member) in a rectangular plate shape, a solar cell element 3 which receives light emitted from a first end face 2c of the light concentrate plate 2, and a frame body 4 which integrally holds the light concentrate plate 2 and the solar cell element 3.

The light concentrate plate 2 has a first main surface 2a serving as a light incident plane, a second main surface 2b opposite to the first main surface 2a, the first end face 2c serving as a light emission plane, and other end faces. In the present embodiment, a reflective layer 5a is provided to each end face other than the first end face 2c.

In this light concentrate plate 2, as depicted in FIG. 2, a fluorescent material 7 of one type is dispersed in a transparent base material 6 made of an organic material with high transparency, for example, an acrylic resin such as PMMA or a polycarbonate resin, or a transparent inorganic material such as glass. In the present embodiment, a PMMA resin is used as the transparent base material 6, and the fluorescent material 7 is dispersed in this resin to form the light concentrate plate 2. Note that the refractive index of this light concentrate plate 2 is equal to that of the PMMA resin, that is, 1.50, because the amount of the dispersed fluorescent material 7 is small.

As this PMMA resin forming the transparent base material 6, one with a material property of not absorbing ultraviolet rays (ultraviolet light) can also be used. That is, a material having a transmission property with respect to a wavelength equal to or lower than 400 nm, for example, XY-0159 (product name) manufactured by Mitsubishi Rayon Co., Ltd., can be used.

In a sunlight spectrum, light equal to or lower than ultraviolet light (in particular, 400 nm) occupies about 10% of the entire light quantity. In resins and glasses, many of them absorb ultraviolet rays. Also, recently, in order to improve light resistance, an ultraviolet absorber may be mixed in these materials to absorb ultraviolet light.

In the case of the ultraviolet-absorbing material as described above, 10% of sunlight corresponding to ultraviolet rays is absorbed in the light concentrate plate 2, and cannot be caused to reach the end face 2c provided with the solar cell element 3. This loss is a large loss in view of effectively using sunlight. To address this, by using a material with less absorption with respect to an ultraviolet region as the transparent base material 6, high efficiency in end-face light gathering can be achieved. However, since ultraviolet light (ultraviolet rays) may become a big factor in degrading the fluorescent material (in particular, organic fluorescent material) as described above, if one with a material property of not absorbing ultraviolet rays is used as the transparent base material 6 in order to achieve high efficiency of light gathering, degradation of the fluorescent material 7 dispersed in the transparent base material 6 may be promoted. However, as will be described further below, since the concentration of the fluorescent material 7 is especially increased in the present invention compared with conventional technology, adverse effects due to degradation of the fluorescent material 7 are mitigated. Therefore, a material with less absorption with respect to the ultraviolet region is used as the transparent base material 6, and high efficiency in end-face light gathering can be achieved.

The fluorescent material 7 is an optical functional material which absorbs ultraviolet light or visible light and emits visible light or infrared light, and an organic fluorescent material is used in the present embodiment.

As this organic fluorescent material, a coumarin-based colorant, a perylene-based colorant, a phthalocyanine-based colorant, a stilbene-based colorant, a cyanine-based colorant, a polyphenylene-based colorant, a xanthene-based colorant, a pyridine-based colorant, an oxazine-based colorant, a chrysene-based colorant, a thioflavine-based colorant, a perylene-based colorant, a pyrene-based colorant, an anthracene-based colorant, an acridone-based colorant, an acridine-based colorant, a fluorene-based colorant, a terphenyl-based colorant, an ethene-based colorant, a butadiene-based colorant, a hexatriene-based colorant, an oxazole-based colorant, a coumarin-based colorant, a stilbene-based colorant, di- and tri-phenylmethane-based colorants, a thiazole-based colorant, a thiazine-based colorant, a naphthalimide-based colorant, an anthraquinone-based colorant, or the like is favorably used. Specifically, a coumarin-based colorant such as 3-(2′-benzothiazolyl)-7-diethylaminocoumarin (coumarin 6), 3-(2′-benzoimidazolyl)-7-N,N-diethylaminocoumarin (coumarin 7), 3-(2′-N-methylbenzoimidazolyl)-7-N,N-diethylaminocoumarin (coumarin 30), or 2,3,5,6-1H,4H-tetrahydro-8-trifluoromethyl quinolizine (9,9a,1-gh) coumarin (coumarin 153); basic yellow 51, which is a coumarin-colorant-based dye; a naphthalimide-based colorant such as solvent yellow 11 or solvent yellow 116; a rhodamine-based colorant such as rhodamine B, rhodamine 6G, rhodamine 3B, rhodamine 101, rhodamine 110, sulforhodamine, basic violet 11, or basic red 2; a pyridine-based colorant such as 1-ethyl-2-[4-(p-dimethylaminophenyl)-1,3-butadienyl)-pyridinium-perchlorate (pyridine 1); furthermore, a cyanine-based colorant or an oxazine-based colorant, or the like is used.

Furthermore, any of various dyes (such as direct dyes, acid dyes, basic dyes, and disperse dyes) can be used as the fluorescent material of the present invention if they are fluorescent.

This fluorescent material 7 is added so as to have a concentration in the light concentrate plate 2 (in the transparent base material 6) higher than a predetermined concentration set in advance, and is approximately uniformly dispersed in the transparent base material 6. The concentration of this fluorescent material will be described in detail further below.

The first main surface 2a and the second main surface 2b of the light concentrate plate 2 are flat surfaces parallel to each other. As for every end face other than the first end face 2c of the light concentrate plate 2, the reflective layer 5a which causes light travelling from the inside of the light concentrate plate 2 toward its outside (light emitted from the fluorescent material) to be reflected toward the inside of the light concentrate plate 2 is provided to the end face via an air layer or directly to the end face not via an air layer. Also, as for the second main surface 2b of the light concentrate plate 2, a reflective layer 5b which causes light travelling from the inside of the light concentrate plate 2 toward its outside (light emitted from the fluorescent material) or light entering from the first main surface 2a but emitted from the second main surface 2b as not being absorbed into the fluorescent material 7 to be reflected toward the inside of the light concentrate plate 2 is provided to the second main surface 2b via an air layer or directly to the second main surface 2b not via an air layer.

As the reflective layers 5a and 5b provided to the end faces and the second main surface 2b, a reflective layer formed of a metal film such as silver or aluminum, a reflective layer formed of a dielectric multilayered film such as an enhanced specular reflector (ESR) reflective film (manufactured by 3M), or the like is used. Also, as the reflective layers 5a and 5b, a specular reflective layer which specularly reflects incident light may be used, or a scatter reflective layer which reflects incident light in a scattered manner may be used. When a scatter reflective layer is used for the reflective layer 5b, the light quantity of light directly oriented to a direction of the solar cell element 3 is increased, and therefore efficiency in light gathering to the solar cell element 3 is increased, and the power generation amount is increased. Also, since reflected light is scattered, variations with time and season of the power generation amount are averaged. Note that a micro-foam polyethylene terephthalate (PET) (manufactured by Furukawa Electric Co., Ltd.) or the like is used as a scatter reflective layer.

The solar cell element 3 has a light receiving surface placed so as to face the first end face 2c of the light concentrate plate 2. This solar cell element 3 is preferably optically bonded to the first end face 2c. As the solar cell element 3, any of known solar cells such as a silicon-based solar cell, a compound-based solar cell, a quantum-dot solar cell, and an organic-based solar cell can be used. Among these, a compound-based solar cell using a compound semiconductor and a quantum-dot solar cell are capable of highly-efficient power generation, and therefore suitable as the solar cell element 3. Examples of the compound-based solar cell include InGaP, GaAs, InGaAs, AlGaAs, Cu(In,Ga)Se₂, Cu(In,Ga)(Se,S)₂, CuInS₂, CdTe, and CdS. Examples of the quantum-dot solar cell include Si and InGaAs. However, a solar cell of another type such as a Si base or organic base can also be used depending on the price or the usage.

Note that while the example is depicted in FIG. 1 where the solar cell element 3 is installed only one end face 2c of the light concentrate plate 2, the solar cell element 3 may be installed on a plurality of end faces of the light concentrate plate 2. When the solar cell element 3 is installed on part of end faces (one side, two sides, or three sides) of the light concentrate plate 2, the reflective layer 5a is preferably installed on an end face not having the solar cell element 3 installed.

The frame body 4 is formed of a frame made of aluminum or the like, causing the first main surface 2a of the light concentrate plate 2 to face outside, and holding four edges of the light concentrate plate 2 in that state and also holding the solar cell element 3 together with the light concentrate plate 2. In an opening which causes the first main surface 2a of the light concentrate plate 2 to face outside, a transparent member such as glass may fit. In this structure, the light concentrate plate 2 has the first main surface 2a facing outside from the frame body 4 serving as a light incident plane and the first end face 2c of the light concentrate plate 2 serving as a light emission plane. Also, each end face of the light concentrate plate 2 is hermetically sealed by the frame body 4 or a seal member not depicted in the drawing, and is also light-shielded by the frame body 4 or the like so as not to be irradiated with external light (sunlight).

The fluorescent material 7 in the light concentrate plate 2 is added and dispersed so as to have a concentration higher than a predetermined concentration set in advance as described above. As the predetermined concentration, a concentration with which the light emission intensity of the light concentrate plate 2 becomes the largest within an increasing range, which will be described further below, is adopted.

First, a relation between the concentration of the fluorescent material 7 in the light concentrate plate 2 (light gathering member), that is, the concentration of the fluorescent material 7 in the transparent base material 6, and light emission intensity obtained from the light concentrate plate 2 due to light emission of the fluorescent material 7 is described.

The fluorescent material 7 is basically mixed and dispersed in the dissolved transparent base material 6 (binder resin such as PMMA). Here, in consideration of the relation between the concentration of the fluorescent material 7 contained in the transparent base material 6 and the light emission intensity of the fluorescent material 7, it can be thought that as the concentration of the fluorescent material 7 increases, the light emission intensity (PL intensity) of the fluorescent material 7 increases (intensifies). This has been revealed from the relation between absorbance and light emission intensity (PL intensity) of the light concentrate plate, which will be described further below.

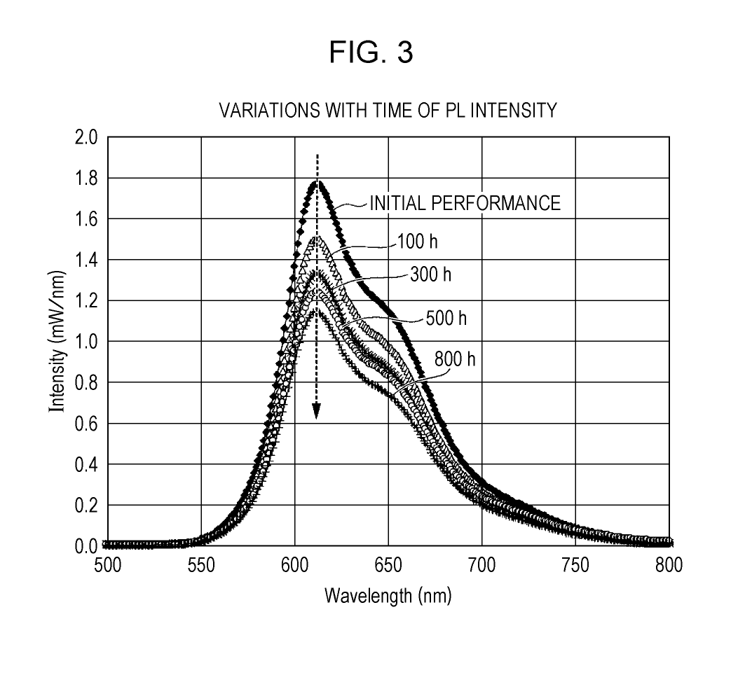

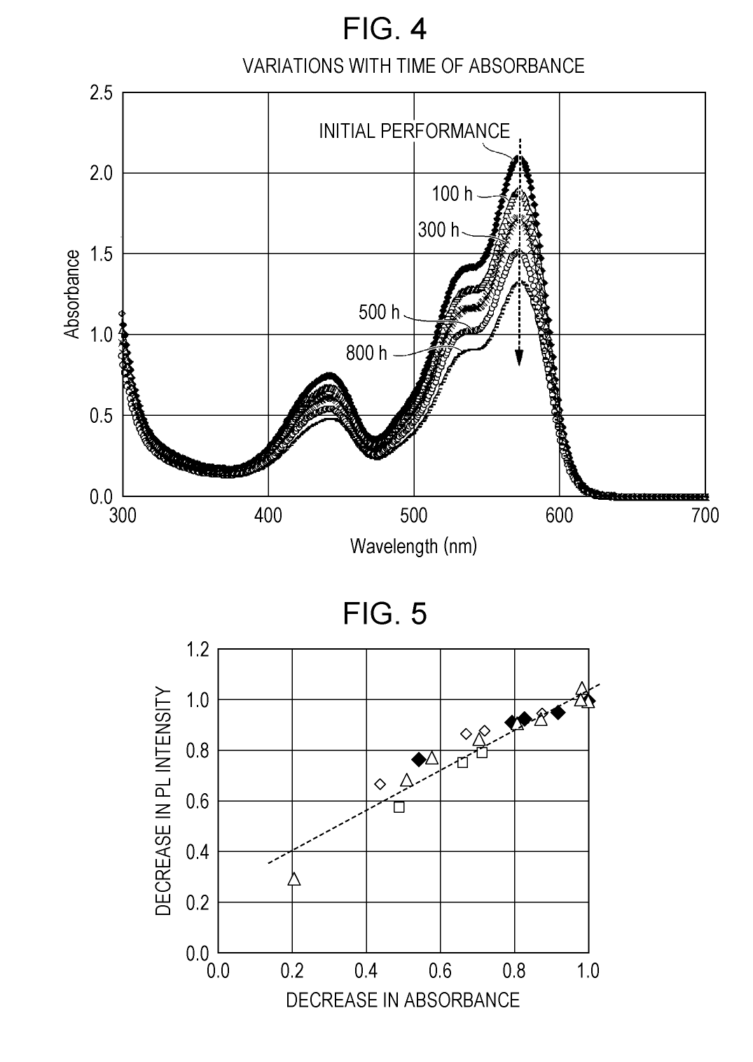

First, the inventors irradiated a light concentrate plate with a fluorescent material dispersed therein with ultraviolet light, and examined variations with time (spectrum variations) of light emission intensity and variations with time (spectrum variations) of absorbance of this light concentrate plate. That is, regarding light emission intensity and absorbance, the inventors examined spectrums at an initial time (initial performance), at the time of irradiation for 100 hours (100 h), at the time of irradiation for 300 hours (300 h), at the time of irradiation for 500 hours (500 h), and at the time of irradiation for 800 hours (800 h). Variations with time of light emission intensity of the light concentrate plate are depicted in FIG. 3, and variations with time of absorbance thereof are depicted in FIG. 4.

Note that a PMMA resin was used as a transparent base material of the light concentrate plate. Also, as a fluorescent material, Lumogen Red (product name) manufactured by BASF with its end group changed so as to be soluble in the PMMA resin was used. A mixture ratio of the fluorescent material was set at 0.2% in a volume ratio with respect to the transparent base material (PMMA resin).

From the results depicted in FIG. 3 and FIG. 4, it was found that as the ultraviolet light irradiation time increases, PL intensity (light emission intensity) and absorbance both decrease. Also, when viewing changes of absorbance curves of FIG. 4, it was found that absorbance decreases while initial curves (absorption spectrums) are maintained, although the shape of each spectrum slightly changes. Similarly, it was found that light emission intensity also decreases while initial curves (light emission spectrums) are maintained, as depicted in FIG. 3.

Based on these results obtained in FIG. 3 and FIG. 4, a relation between decrease in absorbance and decrease in PL intensity is graphically represented in FIG. 5. From FIG. 5, it was found that decrease in absorbance and decrease in PL intensity have a linear correlation and decrease in absorbance directly leads to decrease in PL intensity. Here, absorbance A is found by the following equation:

A=α×L×C,

where α is an absorption coefficient, L is a thickness (thickness of the light concentrate plate), and C is a concentration of the fluorescent material. Also, the thickness L of the light concentrate plate is constant.

Therefore, as can be found from the above equation, the absorbance A is directly proportional to the concentration C of the fluorescent material. That is, decrease in absorbance directly indicates decrease in concentration of the fluorescent material.

Here, decrease in concentration of the fluorescent material means that part of the fluorescent material is degraded upon receiving irradiation of ultraviolet rays to be changed into a non-luminous substance. That is, it can be thought that an excited state (active state) occurs with irradiation of ultraviolet rays and either one or both of degradation of changing the fluorescent material into a non-luminous substance due to the occurrence of a chemical reaction and degradation of breaking bonding between atoms due to irradiation of ultraviolet rays to change the fluorescent material into a non-luminous substance (to lose light emitting capability) occur, thereby seemingly decreasing the concentration of the fluorescent material.

From these results, it was found out that the concentration of the fluorescent material in the light concentrate plate (light gathering member) greatly affects PL intensity (light emission intensity) and, specifically, decrease in concentration of the fluorescent material is correlated with decrease in PL intensity.

Based on these findings, in the present invention, in a relation between the concentration of the fluorescent material 7 in the transparent base material 6 (light concentrate plate 2) and light emission intensity obtained from the light concentrate plate 2 due to light emission of the fluorescent material 7, the concentration of the fluorescent material 7 in the transparent base material 6 (light concentrate plate 2) is set higher than a concentration with which the light emission intensity (PL intensity) becomes the largest in a specific range, which will be described further below.

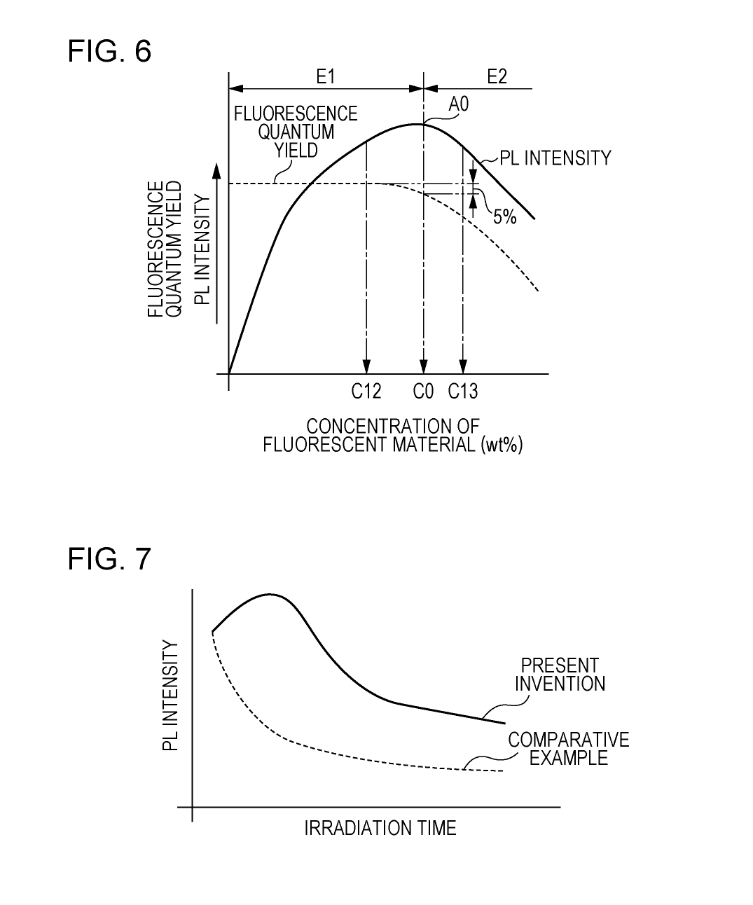

FIG. 6 is a diagram depicting a first example of a relation between the concentration of the fluorescent material 7 contained in the transparent base material 6 (the concentration of the fluorescent material 7 in the light concentrate plate 2) and light emission intensity obtained from the light concentrate plate 2 due to light emission of the fluorescent material 7 and a relation between the concentration of the fluorescent material 7 and a fluorescence quantum yield (light emission quantum yield) of the fluorescent material 7 (hereinafter referred to as a first relation).

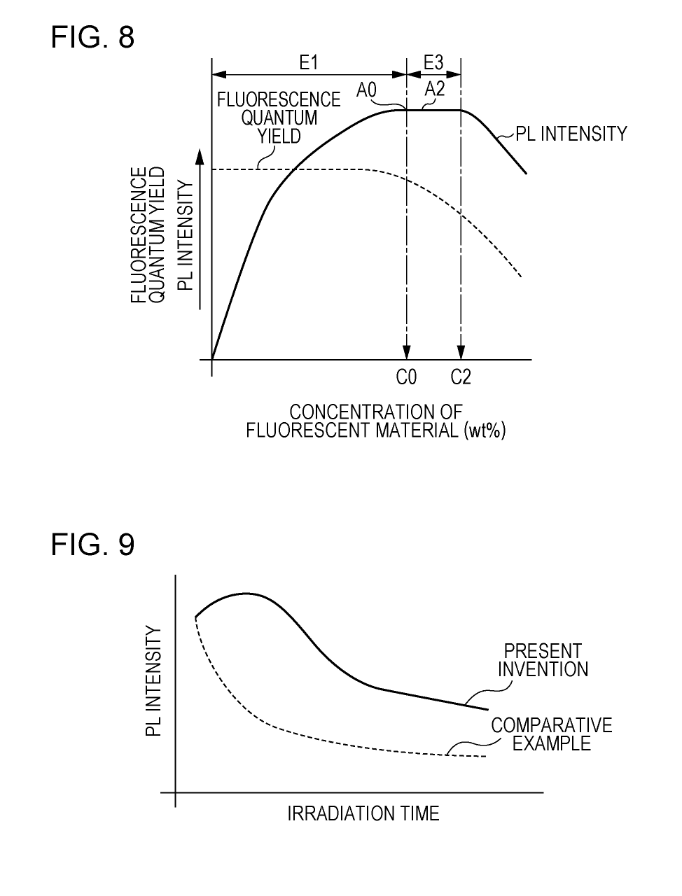

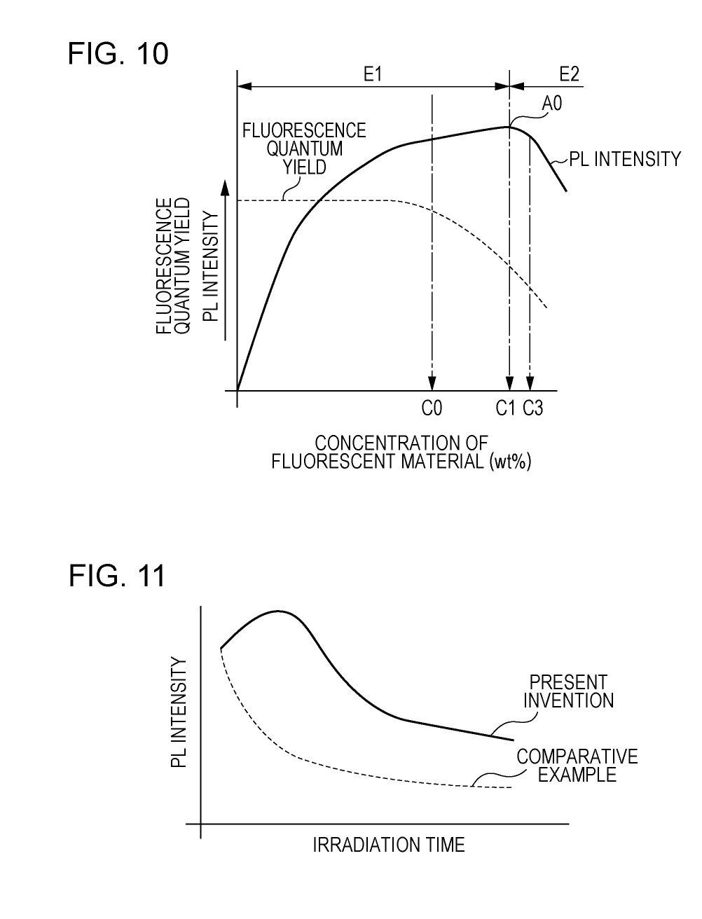

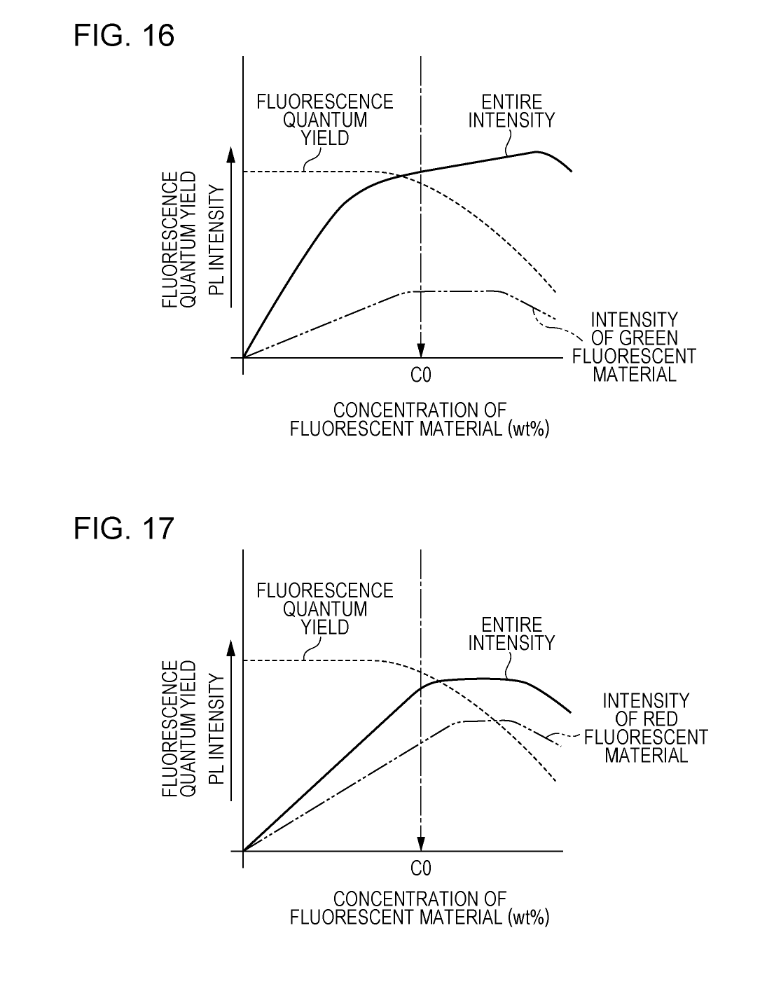

As indicated by a broken line in FIG. 6, the “fluorescence quantum yield”, which is an index for converting irradiated excitation energy to light emission of the fluorescent material, has an approximately constant value maintained as the concentration of the fluorescent material increases, and is then changed to decrease. In the present invention, a fluorescent material concentration with which concentration quenching starts to occur (or “a concentration causing concentration quenching to start to occur”) is defined as a concentration when the fluorescence quantum yield is decreased from the constant value by 5% in a concentration region equal to or higher than a concentration when the fluorescence quantum yield is changed to decrease, as depicted in FIG. 6. Also, concentration quenching occurs with those equal to or higher than this concentration. Note that the fluorescent material concentration with which concentration quenching starts to occur is represented as C0 in FIG. 6 and FIG. 8, FIG. 10, FIG. 16, and FIG. 17, which will be described further below.

As can be found from the results depicted in FIG. 5 above, as the concentration of the fluorescent material increases, the amount of the fluorescent material increases accordingly. Therefore, as indicated by a solid line in FIG. 6, PL intensity increases (intensifies) to some range. That is, an increasing range E1 is provided in which PL intensity increases as the concentration of the fluorescent material increases from zero to a portion near the fluorescent material concentration C0 with which concentration quenching starts to occur. Here, the increasing tendency of PL intensity and an influence of concentration quenching on PL intensity vary depending on the type and concentration of the fluorescent material, a state of dispersion thereof to the binder (transparent base material), and so on.

In FIG. 6, the first relation (first example) of the influence of concentration quenching on PL intensity is depicted. That is, in FIG. 6, a decreasing range E2 in which PL intensity decreases is provided after the increasing range E1. With this, a part between the increasing range E1 and the decreasing range E2 has a maximum value A0, and this maximum value A0 directly serves as a largest value A0 of PL intensity in the increasing range E1. Also, the concentration C0 with which PL intensity has the largest value (maximum value) A0 is the fluorescent material concentration C0 with which concentration quenching starts to occur.

Thus, in the present embodiment, when the decreasing range E2 is provided after the increasing range E1 as described above, the concentration of the fluorescent material 7 in the light concentrate plate 2 is set at a concentration higher than the concentration C0 with which PL intensity has the largest value (maximum value) A0, that is the fluorescent material concentration C0 with which concentration quenching starts to occur. As such, if the concentration is higher than the concentration C0 with which PL intensity has the largest value A0 in the increasing range E1, an effect of the present invention of suppressing the decrease in light emission intensity of the light concentrate plate at an initial stage can be more significantly obtained.

When a fluorescent material (for example, a phosphorescent material) having the relation as indicated by the solid line in FIG. 6 is used as the fluorescent material 7 of the embodiment depicted in FIG. 2, if the concentration of this fluorescent material 7 is set at, for example, a concentration C12 in FIG. 6, which is lower than the concentration C0 in FIG. 6, variations with time of PL intensity of the light concentrate plate 2 having this fluorescent material 7 dispersed therein are as those of a comparative example indicated by a broken line in FIG. 7. Note that these variations with time of PL intensity were found by irradiating the light concentrate plate with ultraviolet light ten times as much as sunlight and measuring variations with time of PL intensity of the light arriving at its end face. In the following, variations with time of PL intensity were found in a manner similar to the above.

As depicted in FIG. 6, in a range equal to or lower than the concentration C12, as the concentration of the fluorescent material decreases, the PL intensity decreases. Therefore, as indicated by a broken line in FIG. 7, as the irradiation time becomes longer, the PL intensity monotonously decreases. This is because a decrease in concentration seemingly occurs due to degradation of the fluorescent material. By contrast, in the present embodiment, the concentration is set at, for example, a concentration C13 in FIG. 6, which is higher than the concentration C0 with which PL intensity has the largest value (maximum value) A0 and higher than the fluorescent material concentration C0 with which concentration quenching starts to occur. Then, variations with time of PL intensity of this light concentrate plate 2 having the fluorescent material 7 dispersed therein are as indicated by a solid line in FIG. 7.

That is, since the concentration of the fluorescent material 7 is set at the concentration C13, which is higher than the fluorescent material concentration C0 with which concentration quenching starts to occur in the present embodiment (present invention), PL intensity increases at an initial stage even when the concentration of the fluorescent material decreases due to degradation, as indicated by the solid line in FIG. 7. This is because, while the concentration of the fluorescent material decreases from C13 to the fluorescent material concentration C0 with which concentration quenching starts to occur, PL intensity increases and also the influence of concentration quenching decreases to increase fluorescence quantum yield, as depicted in FIG. 6. Then, the decrease in concentration of the fluorescent material advances and, when the concentration becomes lower than the fluorescent material concentration C0 with which concentration quenching starts to occur, PL intensity follows a tendency similar to that indicated by the broken line in FIG. 7 to decrease.

However, since the decrease in PL intensity is sufficiently suppressed at the initial stage, the decrease in light emission intensity at the initial stage is sufficiently suppressed in the light concentrate plate 2 according to the present embodiment, compared with, for example, one having the concentration of the fluorescent material 7 set at the concentration C12 in FIG. 6. Therefore, the life as a light gathering member is significantly improved. That is, a long-life fluorescent light concentrate plate can be achieved even if a degradation-prone organic fluorescent material is used. Thus, since the decrease with time of light emission intensity of the light concentrate plate 2 is suppressed, the solar cell module 1 of the present embodiment can offer an excellent light gathering function over a long period of time.

Note that the case has been described in the present embodiment in which the relation between the concentration of the fluorescent material 7 contained in the transparent base material 6 (the concentration of the fluorescent material 7 in the light concentrate plate 2) and light emission intensity obtained from the light concentrate plate 2 due to light emission of the fluorescent material 7 and the relation between the concentration of the fluorescent material 7 and fluorescence quantum yield (light emission quantum yield) of the fluorescent material 7 have the first relation depicted in FIG. 6. However, as described above, the influence of concentration quenching on PL intensity varies depending on the type and concentration of the fluorescent material, a state of dispersion thereof to the binder (transparent base material), and so on, and therefore the relation between the concentration and PL intensity of the fluorescent material 7 and so on may have a relation other than the first relation depicted in FIG. 6.

In the following, as modification examples of the present embodiment, cases are respectively described in which the relation between the concentration of the fluorescent material 7 contained in the transparent base material 6 (the concentration of the fluorescent material 7 in the light concentrate plate 2) and light emission intensity obtained from the light concentrate plate 2 due to light emission of the fluorescent material 7 and the relation between the concentration of the fluorescent material 7 and fluorescence quantum yield (light emission quantum yield) of the fluorescent material 7 have a second relation (first modification example) and a third relation (second modification example).

FIG. 8 is a diagram when the relation between the concentration of the fluorescent material 7 contained in the transparent base material 6 (the concentration of the fluorescent material 7 in the light concentrate plate 2) and light emission intensity obtained from the light concentrate plate 2 due to light emission of the fluorescent material 7 and the relation between the concentration of the fluorescent material 7 and fluorescence quantum yield (light emission quantum yield) of the fluorescent material 7 have the second relation. The second relation depicted in FIG. 8 is different from the first relation depicted in FIG. 6 in that not the decreasing range E2 but a maintaining range E3 is provided after the increasing range E1.

The maintaining range E3 is a range, after the increasing range E1, in which PL intensity maintains an approximately same intensity even if the concentration of the fluorescent material increases. After this maintaining range E3, with reception of the influence of concentration quenching, PL light intensity decreases as the concentration increases. That is, a decreasing range is provided.

Note that a PL intensity A2 in the maintaining range E3 has a largest value (maximum value) in the present example. That is, this PL intensity A2 has the same value as the largest value A0 in the increasing range E1. Also, the lowest concentration in the maintaining range E3 is the fluorescent material concentration C0 with which concentration quenching starts to occur. In the present example, the highest concentration in the maintaining range E3 is assumed to be a concentration C2.

In the first modification example, when the maintaining range E3 is provided after the increasing range E1 as described above, the concentration of the fluorescent material 7 in the light concentrate plate 2 is set at a concentration with which PL intensity has a maximum value, that is, a concentration higher than the concentration with which PL intensity becomes the PL intensity A2. Specifically, the concentration is set at a concentration exceeding the fluorescent material concentration C0 with which PL intensity is the PL intensity A2 and concentration quenching starts to occur.

As such, since the concentration is higher than the fluorescent material concentration C0 with which PL intensity has the largest value A0 in the increasing range E1 and concentration quenching starts to occur in the first modification example, the effect of the present invention of suppressing the decrease in light emission intensity of the light concentrate plate at an initial stage can be more significantly obtained. Therefore, this structure (concentration) is adopted in the first modification example.

When a fluorescent material having a relation as indicated by a solid line in FIG. 8 is used as the fluorescent material 7 depicted in FIG. 2, if the concentration of this fluorescent material 7 is set at a concentration C2 higher than the concentration with which the PL intensity has the maximum value in the first modification example, variations with time of PL intensity of the light concentrate plate 2 having this fluorescent material 7 dispersed therein are as indicated by a solid line in FIG. 9.

Since the concentration of the fluorescent material 7 is set at the concentration C2 higher than the fluorescent material concentration C0 with which concentration quenching starts to occur in the first modification example (the present invention), PL intensity slightly increases even if the concentration of the fluorescent material decreases due to degradation at the initial stage, as indicated by the solid line in FIG. 9. This is because PL intensity is maintained at an approximately same intensity while the concentration of the fluorescent material decreases to C0, but the influence of concentration quenching decreases to increase fluorescence quantum yield, as depicted in FIG. 8. Then, the decrease in concentration of the fluorescent material advances and, when the concentration becomes lower than the fluorescent material concentration C0 with which concentration quenching starts to occur, PL intensity follows a tendency similar to that indicated in a comparative example by the broken line in FIG. 7 (the same curve is indicated by a broken line in FIG. 9) to decrease.

However, since the decrease in PL intensity is sufficiently suppressed at the initial stage, the decrease in light emission intensity at the initial stage is sufficiently suppressed in the light concentrate plate 2 according to the first modification example, compared with, for example, one having the concentration of the fluorescent material 7 set at the concentration C12 in FIG. 6. Therefore, the life as a light gathering member is significantly improved. That is, a long-life fluorescent light concentrate plate can be achieved even if a degradation-prone organic fluorescent material is used. Thus, since the decrease with time of light emission intensity of the light concentrate plate 2 is suppressed, the solar cell module 1 of the first modification example can offer an excellent light gathering function over a long period of time.

FIG. 10 is a diagram when the relation between the concentration of the fluorescent material 7 contained in the transparent base material 6 (the concentration of the fluorescent material 7 in the light concentrate plate 2) and light emission intensity obtained from the light concentrate plate 2 due to light emission of the fluorescent material 7 and the relation between the concentration of the fluorescent material 7 and fluorescence quantum yield (light emission quantum yield) of the fluorescent material 7 have the third relation.

The third relation depicted in FIG. 10 is different from the first relation depicted in FIG. 6 in that the concentration C1 with which PL intensity has the largest value A0 in the increasing range E1 is higher than the fluorescent material concentration C0 with which concentration quenching starts to occur. When the concentration C1 with which PL intensity becomes the largest in the increasing range E1 and the fluorescent material concentration C0 with which concentration quenching starts to occur are different from each other, the concentration of the fluorescent material 7 in the light concentrate plate 2 is set at a concentration higher than the concentration C1 with which PL intensity has the largest value A0 in the present invention.

That is, in the second modification example, the concentration of the fluorescent material 7 in the light concentrate plate 2 is set at a concentration higher than the concentration C1 with which PL intensity has the largest value A0 as described above.

As such, when the concentration is higher than the concentration C1 with which PL intensity has the largest value A0, the effect of the present invention of suppressing the decrease in light emission intensity of the light concentrate plate at an initial stage can be obtained. Therefore, this structure (concentration) is adopted in the present modification example.

When a fluorescent material having a relation as indicated by a solid line in FIG. 10 is used as the fluorescent material 7 depicted in FIG. 2, if the concentration of this fluorescent material 7 is set at, for example, a concentration C3, which is higher than the concentration C1 with which the PL intensity has the largest value A0 in the second modification example, variations with time of PL intensity of the light concentrate plate 2 having this fluorescent material 7 dispersed therein are as indicated by a solid line in FIG. 11.

Since the concentration of the fluorescent material 7 is set at the concentration C3 higher than the concentration C1 with which PL intensity has the largest value A0 in the second modification example (the present invention), PL intensity increases even if the concentration of the fluorescent material decreases due to degradation at the initial stage, as indicated by the solid line in FIG. 11. This is because PL intensity increases while the concentration of the fluorescent material decreases from C3 to C1 and also the influence of concentration quenching decreases to increase fluorescence quantum yield, as depicted in FIG. 10. Then, the decrease in concentration of the fluorescent material advances and, when the concentration becomes lower than the fluorescent material concentration C0 with which concentration quenching starts to occur, PL intensity follows a tendency similar to that indicated by the broken line in FIG. 7 (the same curve is indicated by a broken line in FIG. 11) to decrease.

However, since the decrease in PL intensity is sufficiently suppressed at the initial stage, the decrease in light emission intensity at the initial stage is sufficiently suppressed in the light concentrate plate 2 according to the second modification example, compared with, for example, one having the concentration of the fluorescent material 7 set at the concentration C12 in FIG. 6. Therefore, the life as a light gathering member is significantly improved. That is, a long-life fluorescent light concentrate plate can be achieved even if a degradation-prone organic fluorescent material is used. Thus, since the decrease with time of light emission intensity of the light concentrate plate 2 is suppressed, the solar cell module 1 of the second modification example can offer an excellent light gathering function over a long period of time.

As such, in the first embodiment (including the first modification example and the second modification example), the concentration of the fluorescent material is adjusted to be a predetermined concentration found from FIG. 6, FIG. 8, and FIG. 10, that is, a concentration higher than the concentration with which PL intensity becomes the largest. The concentration with which PL intensity becomes the largest varies depending on the type of the fluorescent material and so on, but normally is 0.1 volume %.

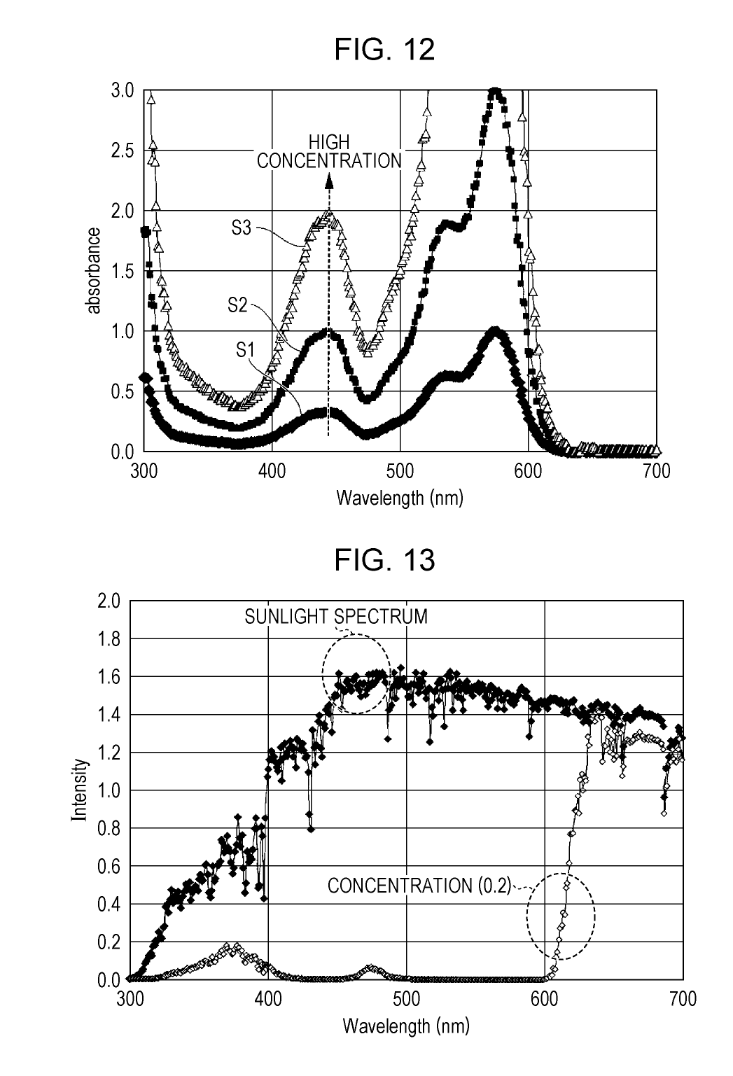

FIG. 12 is a diagram depicting absorption spectrums of light concentrate plates in which the above-described one (Lumogen Red (product name) manufactured by BASF with its end group changed) is used as a fluorescent material and is dispersed in an acrylic resin (transparent base material) of a 50 cm square having a thickness of 2 mm. In FIG. 12, a curve indicated by S1 represents an absorption spectrum in the case of a conventional light concentrate plate having a general fluorescent material concentration, that is, a fluorescent acrylic plate of a 50 cm square having a concentration of 0.02% (a volume ratio with respect to acrylic resin) and a thickness of 2 mm. From this S1, it can be found that while absorbance of a main peak near 570 nm exceeds 1, the absorption spectrum also has a broad absorption peak centering on 450 nm other than this main peak. Therefore, it is difficult to efficiently absorb sunlight with the concentration of 0.02%.

However, when the concentration is increased to 0.1% (a volume ratio with respect to acrylic resin) as in a curve indicated by S2 and, furthermore, the concentration is increased to 0.2% (a volume ratio with respect to acrylic resin) as in a curve indicated by S3 in FIG. 12, absorbance increases, and sunlight can be efficiently absorbed. That is, since absorbance of 450 nm is 2 in the curve indicated by S3, 99% or higher light can be absorbed. That is, by using this fluorescent material, light in a considerably wide wavelength range up to 600 nm can be absorbed even singly.

FIG. 13 is a graph depicting a spectrum after sunlight is absorbed in the light concentrate plate corresponding to the curve S3 with the fluorescent material concentration set at 0.2%. In FIG. 13, a spectrum of sunlight is also depicted. Furthermore, the spectrum after sunlight is absorbed is represented with a concentration set at (0.2).

From FIG. 13, it was found that 30% of sunlight can be absorbed in the light concentrate plate corresponding to the curve S3. This energy can be converted to light by the light concentrate plate and the solar cell element at high efficiency of 85%.

The original fluorescence quantum yield of the fluorescent material is on the order of 95% (for example, in the case of 0.02 wt %). However, since the concentration is increased in the present example, fluorescence quantum yield decreases. From this, it can be thought that the concentration (0.2%) in the present example is higher than the fluorescent material concentration with which concentration quenching starts to occur.

Note that light emitted in the light concentrate plate 2 is subjected to uniform light irradiation in all azimuths. Among these, an extraction loss due to a difference in refractive index between the light concentrate plate 2 and the air layer (light beams emitted to the upper and lower surfaces) is 25%, and surface reflection of the upper surface is on the order of 4%. Therefore, energy reaching the solar cell on the end face 2c is 18% at MAX. However, due to self absorption in a light guiding process, light actually gathered on the end face 2c of the light concentrate plate 2 was 12%.

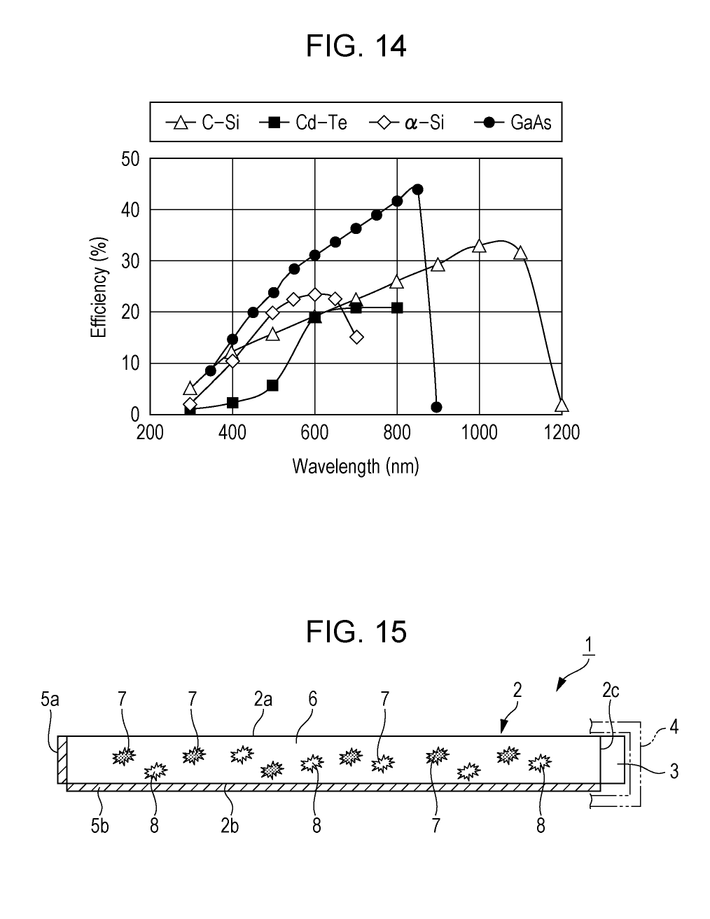

On the end face of the light concentrate plate of the present example, a solar cell in a GaAs single-layer structure was installed. A relation between conversion efficiency and wavelength of each of solar cells of various types in addition to GaAs is depicted in FIG. 14. Since the fluorescent material of the present example emits light centering on 650 nm, conversion efficiency of GaAs at that time is 42% as depicted in FIG. 14. Therefore, the power generation amount at the time of incidence of sunlight of 1 Sun (100 mW/cm²) is 12.6 W @ a 50 cm square.

### Second Embodiment

Next, a second embodiment of the solar cell module according to the present invention is described.

FIG. 15 is a sectional view of a main part side of the solar cell module of the second embodiment. The solar cell module depicted in FIG. 15 is different from the solar cell module 1 of the first embodiment depicted in (a) and (b) of FIG. 1 in that fluorescent materials of not one type but two types (a plurality of types) are dispersed in the light concentrate plate 2 (light gathering member).

That is, in the present embodiment, in addition to the fluorescent material 7 for red light emission used in the first embodiment (Lumogen Red (product name) manufactured by BASF with its end group changed), that is, the fluorescent material 7 (red fluorescent material) with its peak wavelength of a light emission spectrum in a red wavelength region, a fluorescent material 8 for green light emission, that is, the fluorescent material 8 (green fluorescent material) with its peak wavelength of a light emission spectrum in a green wavelength region is dispersed in the light concentrate plate 2. Here, as the green fluorescent material 8, one obtained by modifying a Lumogen fluorescent material from BASF so as to be soluble in the PMMA resin is used.

As such, when fluorescent materials of a plurality of types are mixed and used, a fluorescent material on a short wavelength side is color-converted to a fluorescent material on a longest wavelength side. That is, only fluorescence emitted from a fluorescent material with the largest peak wavelength of the light emission spectrum among the fluorescent materials is received by the solar cell element 3. Therefore, if the fluorescent material is a mix-based fluorescent material, the fluorescent material is eventually governed by behaviors of the fluorescent material on the longest wavelength side.

Of the light concentrate plates 2 of these fluorescent materials 7 and 8, at least one of these has a concentration higher than the concentration with which PL intensity becomes the largest in the increasing range E1 depicted in FIG. 6, FIG. 8, and FIG. 10 and, preferably, both of them have a concentration higher than the concentration with which PL intensity becomes the largest in the increasing range E1. Also, each fluorescent material is desirably adjusted to have a concentration equal to or higher than, for example, the concentration C1 depicted in FIG. 10. Furthermore, in particular, the concentration is preferably higher than the fluorescent material concentration with which concentration quenching starts to occur, and preferably exceeds 0.1 volume %.

When the red fluorescent material 7 has a concentration equal to or lower than the concentration C0 but the green fluorescent material 8 has a concentration higher than the concentration with which PL intensity depicted in, for example, FIG. 16, becomes the largest, PL intensity due to the concentration of the green fluorescent material 8 is similar to that depicted in FIG. 8. However, since green light emission components are energy-converted to red, PL intensity of the entire light concentrate plate becomes as depicted in FIG. 16. That is, by setting the concentration of the green fluorescent material 8 higher than, for example, the concentration C0, the seeming concentration of the red fluorescent material 7 can be sufficiently increased. Thus, even if the concentrations of the fluorescent materials 7 and 8 are set as described above, the decrease in light emission intensity of the light concentrate plate 2 at the initial stage can be sufficiently suppressed.

Also, when the green fluorescent material 8 has a concentration equal to or lower than the concentration with which PL intensity becomes the largest but the red fluorescent material 7 has a concentration higher than the concentration with which PL intensity depicted in, for example, FIG. 17, becomes the largest, PL intensity due to the concentration of the red fluorescent material 7 is similar to that depicted in FIG. 8. As described above, green light emission components are energy-converted to red, and therefore the red fluorescent material 7 is dominant in light emission at the light concentrate plate 2. Since the concentration of the red fluorescent material 7 is sufficiently high, PL intensity of the entire light concentrate plate becomes as depicted in FIG. 17. Therefore, even if the concentrations of the fluorescent materials 7 and 8 are set as described above, the decrease in light emission intensity of the light concentrate plate 2 at the initial stage can be sufficiently suppressed.

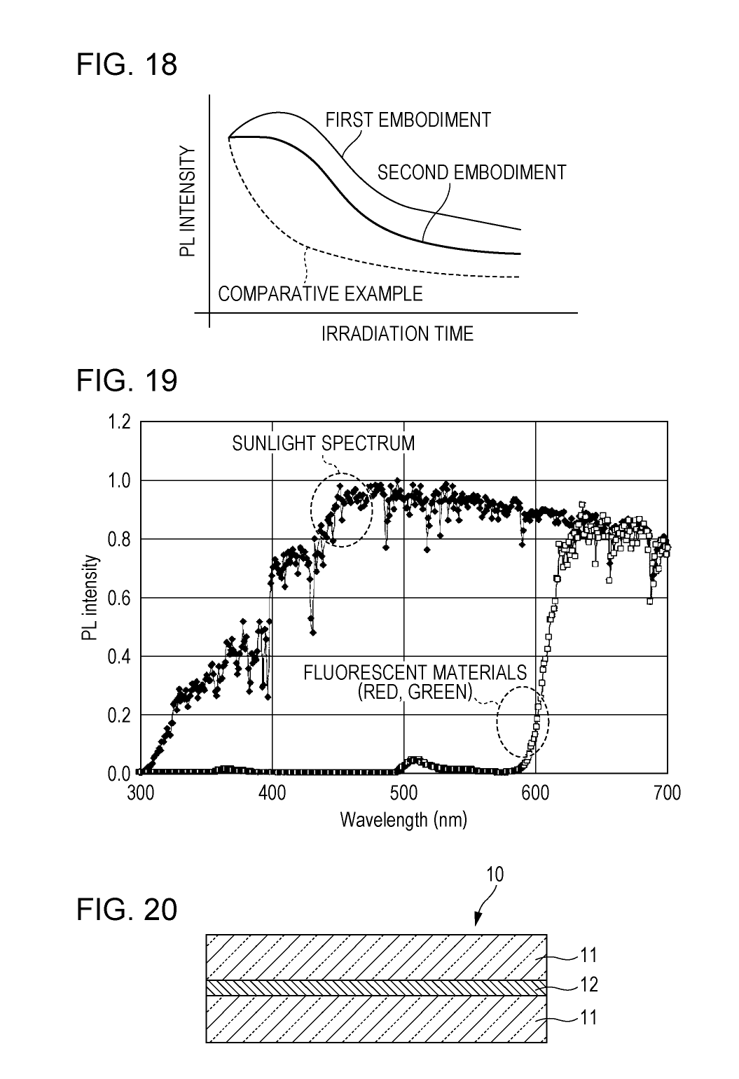

FIG. 18 is a graph depicting variations with time of PL intensity of the light concentrate plate of the present embodiment (second embodiment). Note that as the light concentrate plate of the present embodiment, one having the concentration of the red fluorescent material 7 and the green fluorescent material 8 adjusted as described in the case depicted in FIG. 16 was used. FIG. 18 also depicts variations with time of PL intensity depicted in FIG. 9 in the first embodiment (the broken line indicates a comparative example).

According to FIG. 18, the light concentrate plate of the second embodiment was able to greatly extend the element life, compared with the light concentrate plate of the comparative example in the first embodiment.

On the other hand, the element life is decreased, compared with the first embodiment. Reasons for this can be such that a period with a concentration maintaining PL intensity is decreased by the decrease in concentration of the red fluorescent material 7 and light resistance of the green fluorescent material 8 is worse than that of the fluorescent material 7.

However, even in the light concentrate plate 2 according to the present embodiment, the element life as a light gathering member can be significantly improved. Also, compared with the first embodiment, the power generation amount in the same area of the solar cell element 3 can be improved, compared with the first embodiment.

The intensity of sunlight greatly varies depending on a region for use of the solar cell, such as a cold climate area or right on the equator, and the requirement specification of the element life varies.

In the first embodiment and the second embodiment, the power generation amount and the element life can be controlled by blend conditions and the design of the concentration for use. Therefore, conditions can be determined as appropriate depending on the region for use and requirement specifications.

Note that 0.08% of the red fluorescent material 7 is dispersed in the light concentrate plate 2 and 0.1% of the green fluorescent material 8 is dispersed therein in the present embodiment. With this, the concentration of the green fluorescent material 8 is higher than the concentration with which PL intensity of the fluorescent material 8 depicted in FIG. 16 becomes the largest. The green fluorescent material 8 has a fluorescence quantum yield of 86%, which is considerably lower, compared with, for example, 95% when the concentration is 0.02%. This indicates that concentration quenching occurs in the fluorescent material 8 at 0.1%.

The concentration of the red fluorescent material 7 is, for example, a concentration at an initial stage of the maintaining range E3 depicted in FIG. 8. The fluorescence quantum yield at this time is 90%, which is lower compared with the original efficiency, thereby indicating that concentration quenching occurs.

FIG. 19 is a graph depicting a spectrum of the light concentrate plate 2 formed with a formula of the fluorescent materials 7 and 8 of the present embodiment after sunlight is absorbed. In FIG. 19, a spectrum of sunlight is also depicted. Furthermore, the spectrum after sunlight is absorbed is represented as fluorescent materials (red and green).

From the results depicted in FIG. 19, it was found that 30% of sunlight can be absorbed in the light concentrate plate 2 according to the present embodiment. Also, the absorption ratio was equivalent to that of the first embodiment depicted in FIG. 13.

In the first embodiment, the concentration of the red fluorescent material 7 is deepened in order to absorb a wavelength region of 400 nm to 500 nm of sunlight. In the present embodiment, by mixing the green fluorescent material 8, it was confirmed that it is possible to cover absorption of sunlight in a wavelength region of 400 nm to 500 nm.

Here, although colorants (fluorescent materials) of two colors were mixed, light emitted from the end face contained only red components. The reason for this can be thought such that since the concentration of the green fluorescent material 8 is sufficiently deep and an average of intermolecular distances with the red fluorescent material 7 is equal to or lower than 10 nm, emitted light is color-converted from green to red by energy transfer.

In color conversion by energy transfer, since energy transfer to red is made before green light emission, red light can be emitted without a loss. Also, even without color conversion by energy transfer, with the concentration of the present embodiment, green light emission is immediately absorbed in nearby molecules of the red fluorescent material 7, and light is again emitted as red. The efficiency at this time is green light emission efficiency×red light emission efficiency. Since both are high values, light emission is made with high efficiency.

Eventually, the efficiency of emission from the end face was 14%. The reason for this can be thought such that self absorption decreases by the decrease in concentration of the red fluorescent material 7.

Also, in the present embodiment, as the solar cell element 3, one is used which has spectral sensitivity with a peak wavelength of a light emission spectrum of the red fluorescent material 7, which is a fluorescent material with the largest peak wavelength of the light emission spectrum of the red fluorescent material 7 and the green fluorescent material 8, larger than spectral sensitivity with a peak wavelength of a light emission spectrum of the green fluorescent material 8. Specifically, as the solar cell element 3, as with the first embodiment, a solar cell element in a GaAs single-layer structure is installed on the end face 2c of the light concentrate plate 2. The conversion efficiency of GaAS is 42%. Therefore, the power generation amount at the time of incidence of sunlight of 1 Sun (100 mW/cm²) was 14.7 W @ a 50 cm square.

### Third Embodiment

Next, a third embodiment of the solar cell module according to the present invention is described.

FIG. 20 is a diagram depicting main parts of the solar cell module of the third embodiment, and is a schematic diagram depicting a schematic structure of a light concentrate plate (light gathering member). The solar cell module depicted in FIG. 20 is different from the solar cell module 1 of the first embodiment depicted in (a) and (b) of FIG. 1 in the structure of the light concentrate plate (light gathering member).

A light concentrate plate 10 of the present embodiment is configured so that a fluorescent layer 12 is interposed between paired transparent light guiding layers (transparent layers) 11, 11. As the transparent light guiding layers 11, one similar to the transparent base material 6 is used. In the present embodiment, a transparent PMMA resin substrate having a thickness of 2 mm is used.

The fluorescent layer 12 is, as with the light concentrate plate 2 according to the first embodiment, such that the red fluorescent material 7 is dispersed in a transparent PMMA resin (transparent base material) with a concentration of 0.2% (volume %), and is formed to have a thickness of 1 mm. That is, in the present embodiment, the fluorescent material 7 in the transparent base material in this fluorescent layer 12 has a concentration set higher than the concentration with which PL intensity becomes the largest in the increasing range E1 depicted in FIG. 6, FIG. 8, and FIG. 10.

Note in the present embodiment that the fluorescent material 7 was dispersed in the dissolved PMMA resin so as to have a concentration set in advance (0.2%) and this dispersion fluid was disposed between the paired transparent light guiding layers 11, 11 and cured so as to have a thickness of 1 mm to form the fluorescent layer 12. Here, the light concentrate plate 10 was formed by causing the fluorescent layer 12 to function as a bonding layer. Thus obtained transparent light guiding layers 11, 11 and the fluorescent layer 12 of the light concentrate plate 10 each have a refractive index of 1.5. Therefore, since there is no difference in refractive index at an interface between the transparent light guiding layers 11 and the fluorescent layer 12, refraction is prevented from occurring at the interface.

Note that a method of forming the fluorescent layer 12 is not restricted to the above-described method and any known coating method or film forming method can be adopted, such as a dipping method, a spin coating method, a bar coater method, an inkjet method, a silk printing method, a letterpress printing method, a spray printing method, or the like.

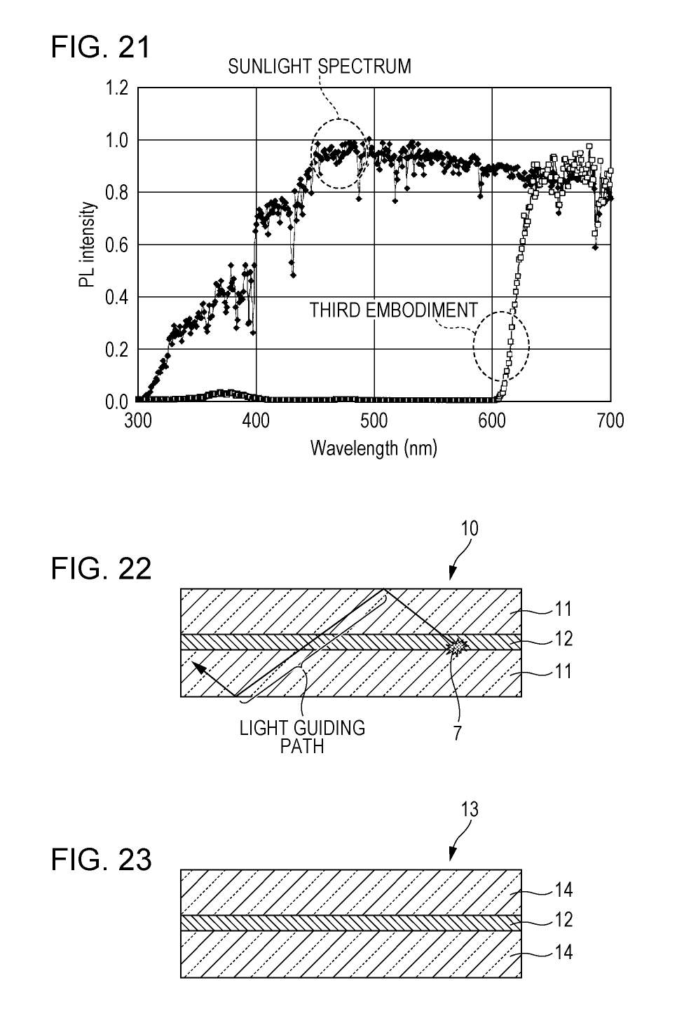

FIG. 21 is a graph depicting a spectrum after sunlight is absorbed by the light concentrate plate 10 according to the present embodiment. In FIG. 21, a spectrum of sunlight is also depicted. Furthermore, the spectrum after sunlight is absorbed is represented as the third embodiment.

From the results depicted in FIG. 21, it was found that 30% of sunlight can be absorbed in the light concentrate plate 10 according to the present embodiment. Also, the absorption ratio was equivalent to that of the first embodiment depicted in FIG. 13. This is because since the absorption coefficient of the fluorescent material 7 is sufficiently high, sunlight can be sufficiently absorbed even with a thin thickness of the fluorescent layer 12 of 1 mm.

Here, the light concentrate plate 10 of the present embodiment has a structure in which the fluorescent layer 12 is interposed between the transparent light guiding layers 11, and is configured so that, as described above, there is no difference in refractive index at the interface between the transparent light guiding layers 11 and the fluorescent layer 12. Therefore, light emitted from the fluorescent layer 12 as indicated by an arrow in FIG. 22 is guided to the entire three layers including two transparent light guiding layers 11, 11 toward the end face. At that time, during one total reflection, the light passes through the transparent light guiding layers 11 twice and through the fluorescent layer 12 once. Thus, the concentration of the fluorescent layer 12 in the light guiding process is substantially thinned to a ratio of the fluorescent layer 12 with respect to the thickness of the entire light concentrate plate 10.

That is, in the light concentrate plate 10 of the present embodiment, since the thickness (1 mm) of the fluorescent layer 12 is ⅕ of the thickness (5 mm) of the entire light concentrate plate 10, although the concentration of the fluorescent material 7 in the fluorescent layer 12 is 0.2%, the concentration can be regarded as 0.04% (=0.2/5) regarding the light guiding process.

From this, in the light concentrate plate 10 of the present embodiment, light guiding can be performed seemingly with a concentration of 0.04%, which is ⅕ compared with the first embodiment, in its light guiding process, thereby allowing a deactivation process due to self absorption to be reduced. Also, in its light emission process, an effect due to a high concentration performance of 0.2%, that is, an effect capable of sufficiently suppressing the decrease in light emission intensity at the initial stage as depicted in FIG. 7, FIG. 9, and FIG. 11 in the first embodiment, can be obtained.

Thus, in the solar cell module of the present embodiment, the decrease in light emission intensity of the light concentrate plate 10 due to the lapse of time is suppressed, and therefore an excellent light gathering function can be offered over a long period of time. Also, since the deactivation process due to self absorption is reduced in the light concentrate plate 10, light gathering efficiency can be increased, compared with the case of using the light concentrate plate 2 with the fluorescent material dispersed in the entire light concentrate plate as described in the first embodiment.

In the light concentrate plate 10 of the present embodiment, light gathering efficiency at the end face was 16% according to the effect described above.

Also in the present embodiment, as with the first embodiment, a solar cell in a GaAs single-layer structure was installed on an end face of the light concentrate plate 10. The power generation amount at the time of incidence of sunlight of 11 Sun (100 mW/cm²) was 16.8 W @ a 50 cm square. Therefore, the fluorescent layer 12 of the present embodiment as the light concentrate plate 10 was able to significantly increase the power generation amount more than the first embodiment, although the concentration of the fluorescent material is equal to that of the light concentrate plate 2 of the first embodiment.

Furthermore, in order to confirm the effect of the present structure, variations with time of PL intensity were compared with those of the light concentrate plate 2 of the first embodiment. As a result, since the concentration of the fluorescent material is equal to that of the first embodiment, an element life curve of the one in the present embodiment approximately matched with that of the one in the first embodiment.

Therefore, by adopting the interposing structure of the present embodiment, in addition to a significant increase in element life, high efficiency of light gathering can be achieved.

### Fourth Embodiment

Next, a fourth embodiment of the solar cell module according to the present invention is described.

FIG. 23 is a diagram depicting main parts of the solar cell module of the fourth embodiment, and is a schematic diagram depicting a schematic structure of a light concentrate plate (light gathering member). The light concentrate plate (light gathering member) of the solar cell module depicted in FIG. 23 is different from the light concentrate plate of the solar cell module of the third embodiment depicted in FIG. 20 in the material of a transparent light guiding layer configuring the light concentrate plate.

That is, a light concentrate plate 13 of the present embodiment is configured so that the fluorescent layer 12 having a thickness of 1 mm is interposed between paired transparent light guiding layers (transparent layers) 14, 14 each having a thickness of 2 mm. While each transparent light guiding layer of the third embodiment is a PMMA resin substrate, that is, a transparent substrate made of an organic material, the transparent light guiding layer 14 in the present embodiment is made of an inorganic material (inorganic compound). As the inorganic material, a base material with ensured transparency, such as glass, quartz, or CaF₂, is used. In the present embodiment, an optical glass, that is, a non-alkali white sheet glass, is used as the transparent light guiding layer 14. This optical glass has a refractive index of 1.53, which is hardly different from the refractive index of the fluorescent layer 12 (1.50). Therefore, refraction hardly occurs at the interface between the transparent light guiding layers 14 and the fluorescent layer 12.

Therefore, the light concentrate plate 13 according to the present embodiment functions equivalently to the light concentrate plate 10 according to the third embodiment. That is, the decrease in light emission intensity at the initial stage can be sufficiently suppressed and, furthermore, the deactivation process due to self absorption can be reduced.

Also, in the light concentrate plate 13 of the present embodiment, as a result of an experiment described below, it was found that degradation of the fluorescent material in the fluorescent layer 12 can be suppressed compared with the light concentrate plate 10 of the third embodiment.

In the experiment, in order to analyze a mechanism of degradation of the fluorescent material in detail, a film of a coating with the red fluorescent material 7 dispersed in a PMMA resin with a concentration of 0.001% (volume %) was formed so as to have a thickness of 10 μm, thereby forming the fluorescent layer 12. Then, this fluorescent layer 12 was irradiated with ultraviolet light, and an absorption spectrum and a light emission spectrum (PL spectrum) after degradation were each measured. The fluorescent layer 12 was made as a thin film with a low concentration because degradation is promoted to determine a change after degradation.

Note that, as a device structure at that time, a device with a structure according to the present embodiment was prepared with the fluorescent layer 12 having a low concentration formed on the optical glass (transparent light guiding layer 14) and a cover glass brought into intimate contact with the fluorescent layer 12 from above. Also, as the structure according to the third embodiment, a device was prepared with the fluorescent layer 12 having a low concentration formed on a PMMA resin plate (transparent light guiding layer 11) and covered with a PMMA film from above.

These devices of two types were fabricated to observe their differences. As a result, it was found that, while approximately 100% of oxygen and moisture can be cut from outside in the device structure interposed between the glasses according to the present embodiment, oxygen and moisture penetrate, although by a trace quantity, in the device structure interposed between the resins according to the third embodiment.

From these observation results and measurement results of an absorption spectrum and a PL spectrum after degradation due to ultraviolet irradiation as described above, the following characteristics were found.

“Device Structure Interposed Between Resins According to Third Embodiment”
Only intensity is dropping without changing the shape of the PL spectrum.
In the absorption spectrum, new absorption is observed in a range equal to or larger than 600 nm, with a decrease in peak intensity.

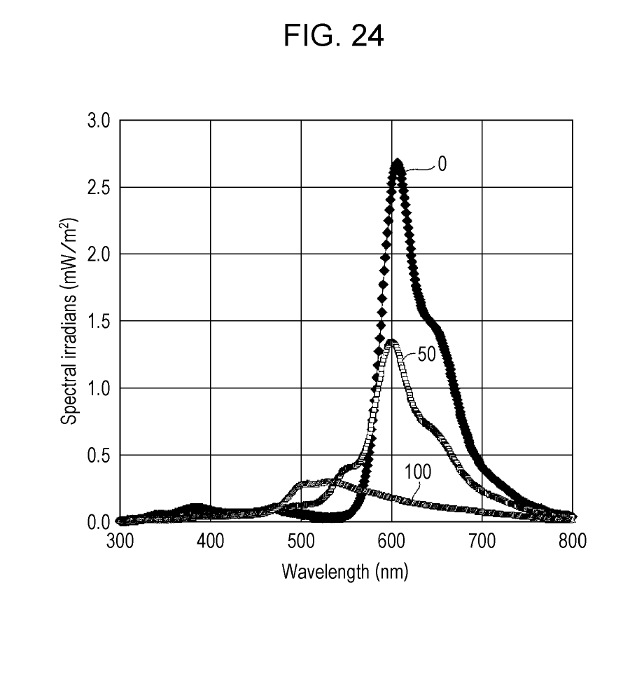

“Device Structure Interposed Between Glasses According to Fourth Embodiment”
As depicted in FIG. 24, the PL spectrum greatly varies as the time of irradiation of ultraviolet rays increases. (In FIG. 24, a curve indicated by “0” represents initial performance with the time of irradiation of ultraviolet rays being zero, a curve indicated by “50” represents a PL spectrum after the lapse of fifty hours of irradiation of ultraviolet rays, and a curve indicated by “100” represents a PL spectrum after the lapse of hundred hours of irradiation of ultraviolet rays.) As can be found from variations in PL spectrum, in the device structure according to the fourth embodiment, while red light was emitted in the initial performance, orange light was emitted after the lapse of fifty hours and green light was emitted after the lapse of hundred hours.
The shape of the absorption spectrum was greatly changed.

The above-described results indicate that the third embodiment interposed between the PMMA resins and the fourth embodiment interposed between the glasses are different in degradation mechanism. As a degradation mechanism, the following can be thought.

“Device Structure Interposed Between Resins According to Third Embodiment”
Ultraviolet rays cause a chemical reaction via moisture or oxygen to occur in molecules of the red fluorescent material, and a product with a wavelength longer than that of the absorption spectrum of its own is formed.
With the chemical reaction, the concentration of the fluorescent material decreases, and degradation is accelerated with the product serving as a quencher.

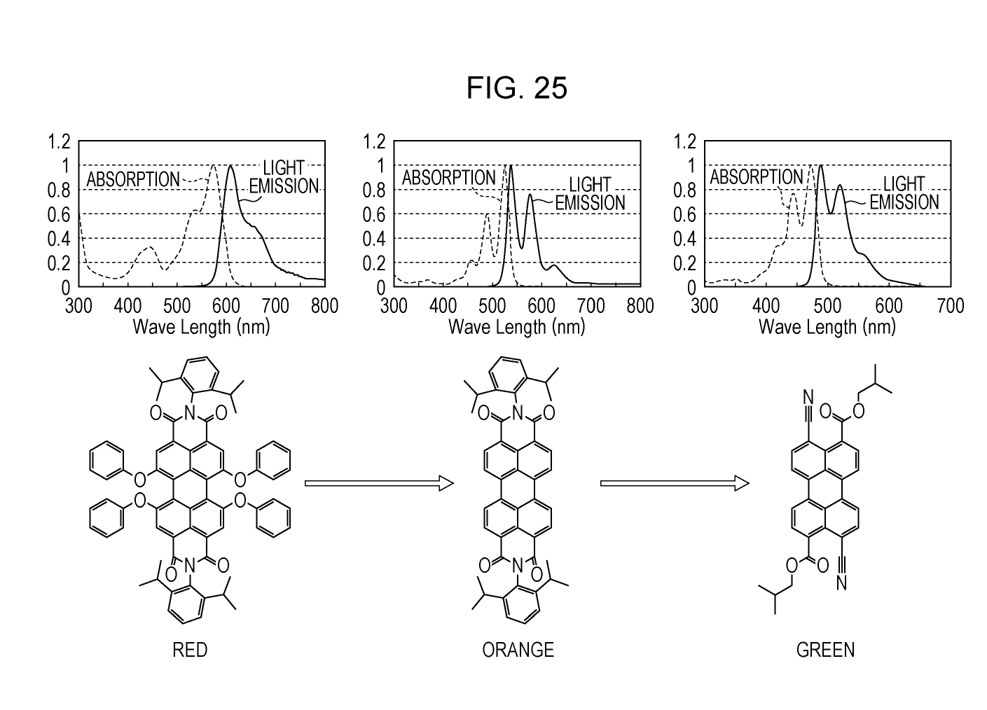

“Device Structure Interposed Between Glasses According to Fourth Embodiment”
Considered from the molecular structure of molecules closed to the fluorescent material 7, as depicted in FIG. 25, when part of functional groups is removed from the red fluorescent material 7, the fluorescent material becomes one which emits orange light. When part of the functional groups is further removed, the fluorescent material becomes one which emits green light. Note that a molecular structure indicated as red in FIG. 25 corresponds to “0” in FIG. 24, a molecular structure indicated as “orange” corresponds to “50” in FIG. 24, and a molecular structure indicated as “green” corresponds to “100” in FIG. 24.
Degradation occurs not by a chemical reaction but by dividing the bonding by ultraviolet rays. Therefore, degradation occurs by ultraviolet rays, but the product is more on a short wavelength side. Thus, unlike the case of the structure interposed between the PMMA resins, degradation is not accelerated with the product serving as a quencher.

That is, although degradation occurs anyway, degradation is accelerated in degradation in the structure interposed between the PMMA resins. By contrast, in the structure interposed between the glasses, since degradation of a boding-dividing type mainly occurs, the product does not serve as a quencher. Therefore, in the long view, a longer life can be achieved in the structure interposed between the glasses.

Thus, in the solar cell module of the present embodiment, the decrease in light emission intensity of the light concentrate plate 13 due to the lapse of time is suppressed, and therefore an excellent light gathering function can be offered over a long period of time. Also, since the deactivation process due to self absorption is reduced in the light concentrate plate 13, light gathering efficiency (end-face extraction efficiency) can be increased, compared with the case of using the light concentrate plate 2 with the fluorescent material dispersed in the entire light concentrate plate as described in the first embodiment. Furthermore, since the product occurring at the time of degradation does not serve as a quencher, a long life can be achieved.

Also, in order to confirm the effect of the present embodiment, a light resistance experiment identical to that of the third embodiment was performed.

As a result, in the present embodiment, it was confirmed that the time taken until PL intensity decreases to 60% with respect to an initial state is extended by 20%, compared with the third embodiment. This is because, by adopting the transparent light guiding layer 14 of optical glass which is an inorganic compound, the entry of oxygen and moisture from outside is blocked to decrease degradation due to a chemical reaction. With generation of components with absorption longer than that of the red fluorescent material 7 being suppressed due to a chemical reaction, a long life was achieved.

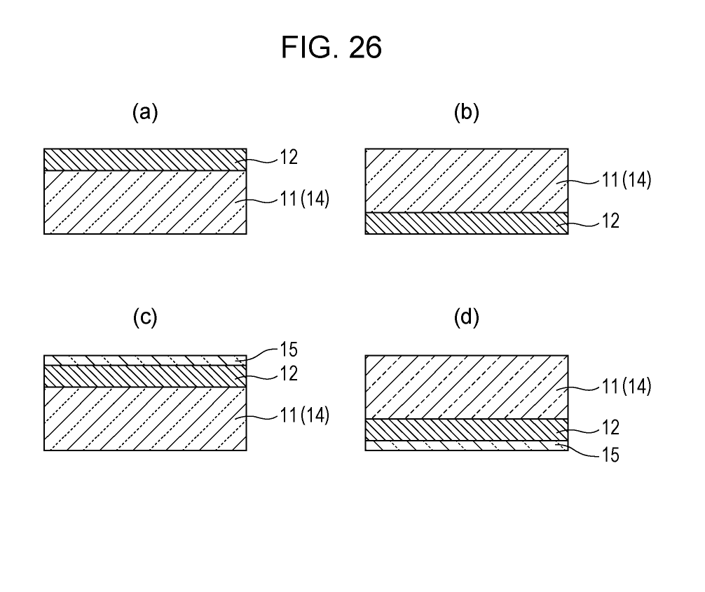

Note that while the structure is such that both surfaces of the fluorescent layer 12 are interposed between the transparent light guiding layers 11 (14) in the third embodiment and the fourth embodiment, the present invention is not limited to this interposing structure. For example, as depicted in (a) and (b) of FIG. 26, the transparent light guiding layer 11 (14) may be disposed only one side of the fluorescent layer 12. In this case, a first main surface side of the light concentrate plate formed of these fluorescent layer 12 and the transparent light guiding layer 11 (14) may be taken as the fluorescent layer 12, or a second main surface side thereof may be taken as the fluorescent layer 12. Here, as for the fluorescent layer 12, a coat film formed by the coating method or film forming method as described can be used.

Also, as the structure in which both surfaces of the fluorescent layer 12 are interposition between transparent layers, as depicted in (c) and (d) of FIG. 26, one may be taken as the transparent light guiding layer 11 (14), and the other may be taken as a transparent layer by a coating film. For example, the structure can be formed by using a PMMA resin substrate having a thickness of 4 mm as the transparent light guiding layer 11, forming on one surface thereof the fluorescent layer 12 made of a coating film having a thickness of 0.5 mm and, furthermore, forming thereon a transparent layer 15 having a thickness of 0.5 mm by the coating method or the like. In that case, the transparent layer 15 may function simply as a protective film.

Note that the present invention is not limited to the above embodiments, and can be variously modified within a range not deviating from the gist of the present invention.

For example, while the case of using an organic fluorescent material as a fluorescent material has been described in the above embodiments, even an inorganic fluorescent material may have a tendency similar to that of an organic fluorescent material, and therefore the inorganic fluorescent material can also be used as a fluorescent material in the present invention.

Also, while fluorescent materials of two types, that is, a red fluorescent material and a green fluorescent material, are used in the second embodiment, fluorescent materials of three or more types can be used. Also in this case, as for concentrations of the fluorescent materials of these three or more types in the transparent base material (in the light concentrate plate), the concentration of at least one type is assumed to be higher than the concentration with which the PL intensity becomes the largest in the increasing range E1 depicted in FIG. 6, FIG. 8, and FIG. 10. Furthermore, the concentration, in particular, is preferably higher than the fluorescent material concentration with which concentration quenching starts to occur and is preferably higher than the concentration exceeding 0.1 volume %.

Still further, while the case of using a fluorescent material of one type, that is, a red fluorescent material, has been described in the third embodiment and the fourth embodiment, as with the second embodiment, a plurality of types (two types or three types or more) may be used.

Still further, while the light concentrate plate (light gathering member) and the fluorescent layer in the light concentrate plate is configured of one layer in the above embodiments, for example, a fluorescent layer serving as a sacrificial layer may be disposed ahead of these light concentrate plate and fluorescent layer (the light incident side). In that case, as for the fluorescent layer serving as a sacrificial layer, the concentration of the fluorescent material may equal to or lower than a concentration defined by the present invention.

[Photovoltaic Power Generation Device]

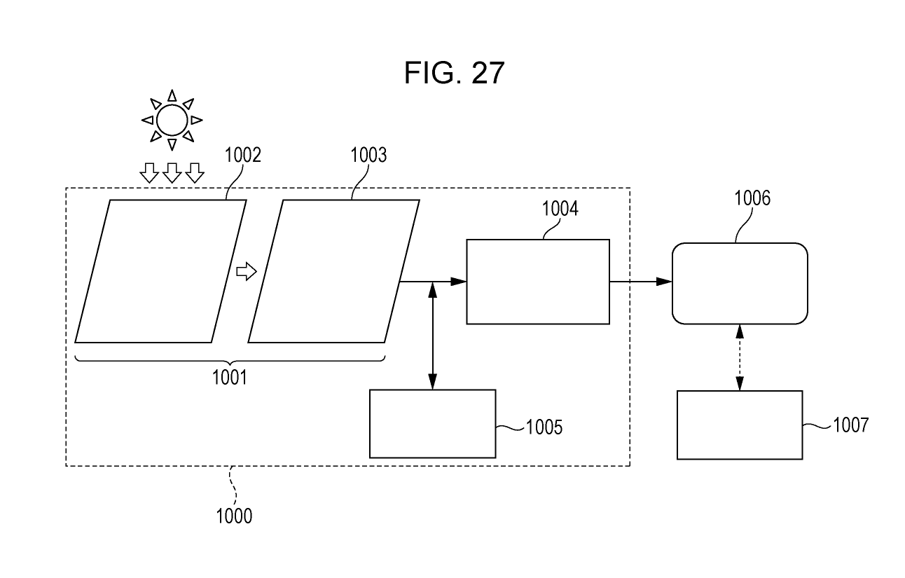

FIG. 27 is a schematic structural view of a photovoltaic power generation device 1000.

The photovoltaic power generation device 1000 includes a solar cell module 1001 which converts sunlight energy to electric power, an inverter (direct-current/alternating-current converter) 1004 which converts direct-current power outputted from the solar cell module 1001 to alternating-current power, and a storage battery 1005 which stores direct-current power outputted from the solar cell module 1001.

The solar cell module 1001 includes a light gathering member (light concentrate plate) 1002 which gathers sunlight and a solar cell element 1003 which generates power with sunlight gathered by the light gathering member 1002. As this solar cell module 1001, for example, the solar cell modules described in the first embodiment to the fourth embodiment can be favorably used.

The photovoltaic power generation device 1000 supplies electric power to an external electronic device 1006. To the electronic device 1006, electric power is supplied as required from an auxiliary power source 1007.

Because of including the above-described solar cell module according to the present embodiment, the above-structured photovoltaic power generation device 1000 can offer an excellent light gathering function over a long period of time.

Also, in the solar cell module, a maintaining range in which the light emission intensity is maintained to have a same intensity even when the concentration increases is provided after the increasing range, and the concentration of the fluorescent material in the transparent base material is set higher than a concentration with which the light emission intensity has a maximum value.

Furthermore, in the solar cell module, the concentration of the fluorescent material in the transparent base material is equal to or higher than a concentration with which concentration quenching starts to occur.

Still further, in the solar cell module, a concentration with which concentration quenching starts to occur is present in a concentration range in the increasing range.

Still further, in the solar cell module, the concentration of the fluorescent material in the transparent base material is a concentration exceeding 0.1 volume %.

Still further, in the solar cell module, the fluorescent material includes fluorescent materials of a plurality of types with mutually different peak wavelengths of light emission spectrums, and a concentration of at least one type of the fluorescent materials of the plurality of types is set higher than a concentration with which the light emission intensity becomes largest in the increasing range.

Still further, in the solar cell module, concentrations of all of the fluorescent materials of the plurality of types are set higher than the concentration with which the light emission intensity becomes largest in the increasing range.

Still further, in the solar cell module, only fluorescence emitted from a fluorescent material with a largest peak wavelength of a light emission spectrum among the fluorescent materials of the plurality of types is received by the solar cell element.

Still further, in the solar cell module, spectral sensitivity of the solar cell element with a peak wavelength of a light emission spectrum of a fluorescent material with a largest peak wavelength of the light emission spectrum of the fluorescent materials of the plurality of types is greater than spectral sensitivity of the solar cell element with a peak wavelength of a light emission spectrum of any one of other fluorescent materials provided in the light gathering member.

Still further, in the solar cell module, the light gathering member is formed to include a fluorescent layer including the fluorescent material and a transparent light guiding layer provided on at least one side of the fluorescent layer.

Still further, in the solar cell module, the transparent light guiding layer is made of an inorganic compound.

Still further, in the solar cell module, the fluorescent material is an organic fluorescent material.

A photovoltaic power generation device of the present invention includes the solar cell module.

### INDUSTRIAL APPLICABILITY

The present invention can be used in a solar cell module and photovoltaic power generation device.

### REFERENCE SIGNS LIST

1 solar cell module
2 light concentrate plate (light gathering member)
2a first main surface
2b second main surface
2c end face
3 solar cell element
6 transparent base material
7 fluorescent material
8 fluorescent material
10 light concentrate plate (light gathering member)
11 transparent light guiding layer
12 fluorescent layer
13 light concentrate plate (light gathering member)
14 transparent light guiding layer
15 transparent layer
1000 photovoltaic power generation device
L light

1. A solar cell module comprising a light gathering member formed of a fluorescent material provided in a transparent base material, the light gathering member absorbing light entering from outside by the fluorescent material and causing light emitted from the fluorescent material to propagate inside to be emitted from at least one end face, and a solar cell element installed on the end face of the light gathering member, the solar cell element receiving the light emitted from the end face and generating electric power, wherein
the fluorescent material in the light gathering member has an increasing range in which, in a relation between a concentration of the fluorescent material in the transparent base material and light emission intensity obtained from the light gathering member with light emission of the fluorescent material, the light emission intensity increases as the concentration increases from zero, and
the concentration of the fluorescent material in the transparent base material is set higher than a concentration with which the light emission intensity becomes largest in the increasing range.

2. The solar cell module according to claim 1, wherein
a maintaining range in which the light emission intensity is maintained to have a same intensity even when the concentration increases is provided after the increasing range, and
the concentration of the fluorescent material in the transparent base material is set higher than a concentration with which the light emission intensity has a maximum value.

3. The solar cell module according to claim 1, wherein
the concentration of the fluorescent material in the transparent base material is equal to or higher than a concentration with which concentration quenching starts to occur.

4. The solar cell module according to claim 1, wherein
a concentration with which concentration quenching starts to occur is present in a concentration range in the increasing range.

5. The solar cell module according to claim 1, wherein
the concentration of the fluorescent material in the transparent base material is a concentration exceeding 0.1 volume %.

6. The solar cell module according to claim 1, wherein
the fluorescent material includes fluorescent materials of a plurality of types with mutually different peak wavelengths of light emission spectrums, and
a concentration of at least one type of the fluorescent materials of the plurality of types is set higher than a concentration with which the light emission intensity becomes largest in the increasing range.

7. The solar cell module according to claim 6, wherein
concentrations of all of the fluorescent materials of the plurality of types are set higher than the concentration with which the light emission intensity becomes largest in the increasing range.

8. The solar cell module according to claim 6, wherein
only fluorescence emitted from a fluorescent material with a largest peak wavelength of a light emission spectrum among the fluorescent materials of the plurality of types is received by the solar cell element.

9. The solar cell module according to claim 6, wherein
spectral sensitivity of the solar cell element with a peak wavelength of a light emission spectrum of a fluorescent material with a largest peak wavelength of the light emission spectrum of the fluorescent materials of the plurality of types is greater than spectral sensitivity of the solar cell element with a peak wavelength of a light emission spectrum of any one of other fluorescent materials provided in the light gathering member.

10. The solar cell module according to claim 1, wherein
the light gathering member is formed to include a fluorescent layer including the fluorescent material and a transparent light guiding layer provided on at least one side of the fluorescent layer.

11. The solar cell module according to claim 10, wherein
the transparent light guiding layer is made of an inorganic compound.

12. The solar cell module according to claim 1, wherein
the fluorescent material is an organic fluorescent material.

13. A photovoltaic power generation device comprising the solar cell module according to claim 1.
